(19) United States
(12) Patent Application Publication
(10) Pub. No.: US 2017/0162501 A1
(43) Pub. Date: Jun. 8, 2017

(54) CRACK STOP LAYER IN INTER METAL LAYERS

(71) Applicant: GLOBALFOUNDRIES Singapore Pte. Ltd., Singapore (SG)

(72) Inventors: Wanbing YI, Singapore (SG); Cuiling ZHOU, Singapore (SG); Juan Boon TAN, Singapore (SG)

(21) Appl. No.: 14/956,401

(22) Filed: Dec. 2, 2015

(51) Int. Cl. H01L 23/522; H01L 23/532; H01L 21/768; H01L 23/528

(52) U.S. Cl. CPC H01L 23/5226; H01L 23/528; H01L 23/5329; H01L 21/76805; H01L 21/76831; H01L 21/76877

(57) ABSTRACT

Devices and methods for forming a device are presented. The method includes providing a substrate prepared with interlevel dielectric (ILD) layers having interconnect levels. Each of the ILD layers has a metal level dielectric which includes one or more metal lines and a via level dielectric which includes one or more via contacts. A crack stop layer is formed within one of the via level dielectric of one of the ILD layers. The crack stop layer prevents crack formation in the ILD layer or crack propagation to underlying ILD layer.

### BACKGROUND

Fabrication of integrated circuits (ICs) involves the formation of features on a substrate that make up circuit components, such as transistors, resistors and capacitors. The components are interconnected, enabling the IC to perform the desired functions. Interconnections are formed by forming contacts and conductive lines in an interlevel dielectric (ILD) or inter-metal dielectric (IMD) layer. A via contact is disposed in a via opening or contact hole formed in a lower portion and a metal line is disposed in a trench which is generally wider than the contact hole in an upper portion of the dielectric layer. The via contact serves as a contact to a component while the conductive line connects the component to, for example, other components.

To increase throughput, a plurality of ICs are fabricated on a wafer in parallel. As the design of the transistor gets smaller, more transistor units are placed within one wafer. The denser chip design may reduce the support and strength structure in the wafer. Also, larger wafer size is preferred as it reduces production cost. However, certain designs, although applicable in smaller wafers, may create cracks in a larger wafer due to a larger stress level built up in the larger wafer. We have observed that wafers with larger diameter suffer yield losses and reliability issues due to cracks initiated from weak areas of an ILD or IMD layer which may propagate to underlying layers particularly where the design generates high stress levels when subject to thermal processing.

From the foregoing discussion, it is desirable to create a scheme to prevent crack initiation and propagation in the wafers.

### SUMMARY

Embodiments generally relate to semiconductor devices and methods for forming a device. In one embodiment, a method for forming a device is disclosed. The method includes providing a substrate prepared with interlevel dielectric (ILD) layers having interconnect levels. Each of the ILD layers has a metal level dielectric which includes one or more metal lines and a via level dielectric which includes one or more via contacts. A crack stop layer is formed within one of the via level dielectric of one of the ILD layers. The crack stop layer prevents crack formation in the ILD layer or crack propagation to underlying ILD layer.

In another embodiment, a device is presented. The device includes a substrate prepared with interlevel dielectric (ILD) layers having interconnect levels. Each of the ILD layers has a metal level dielectric which includes one or more metal lines and a via level dielectric which includes one or more via contacts. A crack stop layer is disposed within one of the via level dielectric of one of the ILD layers. The crack stop layer prevents crack formation in the ILD layer or crack propagation to underlying ILD layer.

These and other advantages and features of the embodiments herein disclosed will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1a-1c show cross-sectional views of various embodiments of a device which includes a crack stop layer disposed in a portion of a via level dielectric of an ILD level;

FIG. 2 shows a cross-sectional view of another embodiment of a device which includes crack stop layers disposed in various ILD levels;

FIGS. 3a-3l show an embodiment of a process for forming a device; and

FIGS. 4a-4f show another embodiment of a process for forming a device.

### DETAILED DESCRIPTION

Embodiments of the present disclosure generally relate to devices, such as semiconductor devices or ICs, and methods for forming a device. Other suitable types of devices may also be useful. The devices can be any type of IC, for example dynamic or static random access memories, signal processors, or system-on-chip (SoC) devices. The devices can be incorporated into, for example, consumer electronic products, such as computers, cell phones, and personal digital assistants (PDAs). Incorporating the devices in other applications may also be useful. The methods as will be described below may be applicable to 0.18 micron technology. The methods as will be described below may also be suitable for other technology nodes.

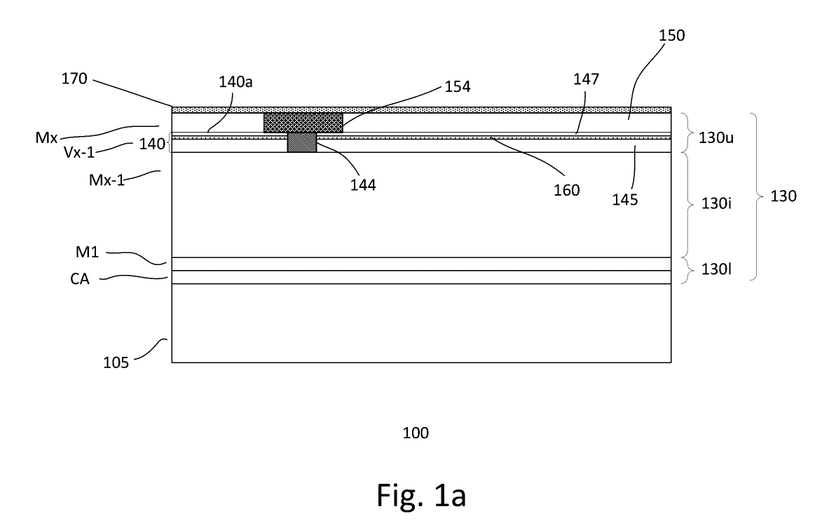

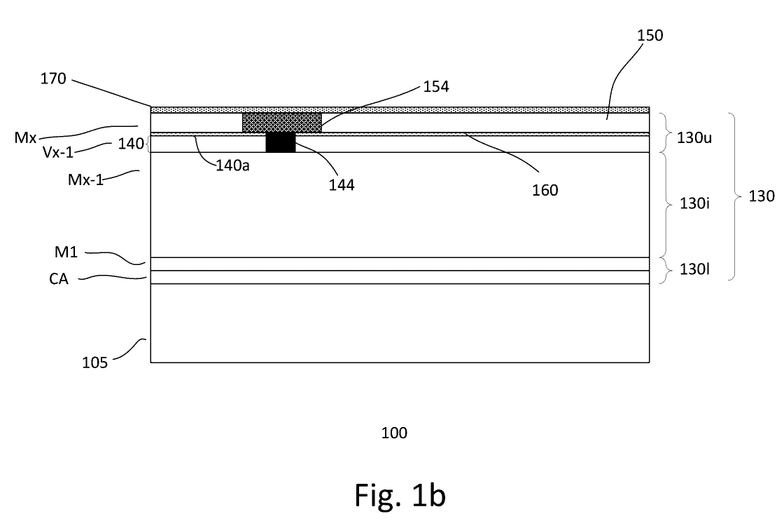

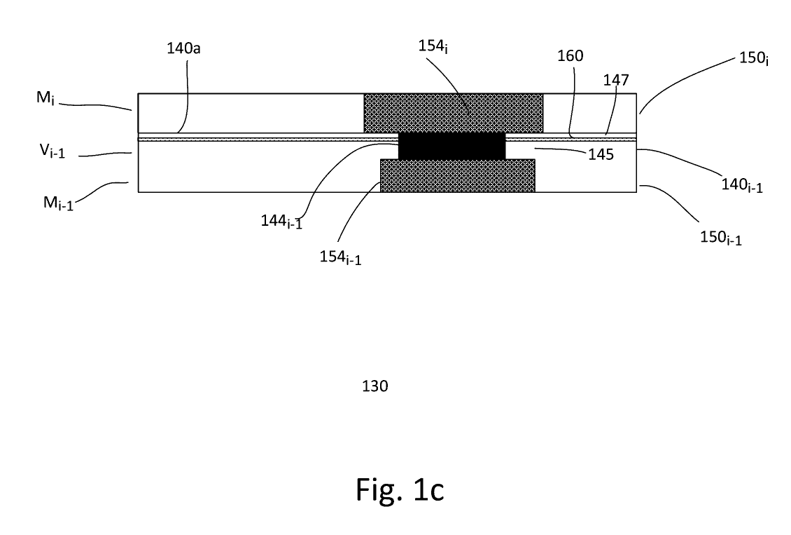

FIG. 1a shows an embodiment of a device 100. The device, for example, is an integrated circuit (IC). Other types of devices may also be useful. The device includes a substrate 105. The substrate, for example, is a semiconductor substrate, such as a silicon substrate or wafer. For example, the substrate may be a lightly doped p-type or n-type substrate. Other types of semiconductor substrates, including crystalline on insulator (COI) substrates, such as silicon-on insulator (SOI) substrates, may also be useful.

The substrate may include various types of regions. Such regions, for example, may include high voltage (HV), memory and logic regions. HV devices are formed in the HV regions, logic devices are formed in the logic regions while memory devices are formed in the memory or array regions. The devices, for example, are metal oxide semiconductor (MOS) transistors. Other suitable types of devices or device regions may also be useful.

Front end of line (FEOL) process (not shown) is performed on the substrate 105. Isolation regions, such as shallow trench isolation (STI) regions, are formed to isolate different device regions. Device wells are formed for p-type and n-type transistors for a complementary MOS (CMOS) device. Separate implants may be employed to form different doped wells using, for example, implant masks, such as photoresist masks. Gates are formed by, for example, forming gate oxide layer, such as thermal silicon oxide followed by a gate electrode layer, such as polysilicon. Separate processes may be performed for forming gate dielectrics of the different voltage transistors. For example, HV transistor will have a thicker gate dielectric than a low voltage (LV) transistor.

The gates are formed by patterning the gate layers. Source/drain (S/D) regions are formed adjacent to the gates. The S/D regions are heavily doped n-type or p-type regions depending on the type of device. Lightly doped regions may be provided for the S/D regions. Dielectric sidewall spacers may be provided on sidewalls of the gates to facilitate forming lightly and heavily doped regions. Separate implants may be employed to form different doped regions using, for example, implant masks, such as photoresist mask.

After forming the transistors, back-end-of-line (BEOL) processing is performed. The BEOL process includes forming interconnects in interlevel dielectric (ILD) layers 130. The interconnects connect the various components of the IC to perform the desired functions. An ILD layer includes a metal level and a via or contact level. Generally, the metal level includes conductors or metal lines while the via or contact level includes via contacts or contact plugs. The metal lines and contacts may be formed of a metal, such as aluminum, tungsten or a combination thereof. Other suitable types of metal, alloys, or conductive materials, such as copper or copper alloy, may also be useful. In one embodiment, the metal lines and contacts may have different materials. In other embodiments, the metal lines and contacts may be formed of the same material.

A device may include a plurality of ILD layers or levels. For example, x number of ILD levels may be provided. For example, 5 ILD levels (x=5) may be provided. Other suitable number of ILD levels may also be useful. The number of ILD levels may depend on, for example, design requirements or the logic process involved. A metal level of an ILD level may be referred to as Mᵢ, where i is the i^{th} ILD level of x ILD levels. A via or contact level of an ILD level may be referred to as Vᵢ₋₁, where i is the i^{th} ILD level of x ILD levels. For the first via or contact level, it may be referred to as CA or V₀. The first metal level or first interconnect layer may be referred to as M₁.

The BEOL process, for example, commences by forming a dielectric layer over the transistors and other components formed in the FEOL process. The dielectric layer, for example, may be silicon oxide formed by chemical vapor deposition (CVD). The dielectric layer serves as a premetal dielectric layer (PMD) or first contact layer of the BEOL process. The dielectric layer may be referred to as CA level of the BEOL process. Contacts are formed in the CA level dielectric layer. The contacts may be formed by a single damascene process. Via openings are formed in the dielectric layer using mask and etch techniques. For example, a patterned resist mask with openings corresponding to the vias is formed over the dielectric layer. An anisotropic etch, such as reactive ion etch (RIE), is performed to form via openings, exposing contact regions below, such as S/D regions and gates. A conductive layer, such as tungsten, is deposited on the substrate filling the openings. The conductive layer may be formed by CVD. Other suitable techniques may also be useful. A planarization process, such as chemical mechanical planarization (CMP), is performed to remove excess conductive material, leaving contact plugs in the CA level.

After forming contacts in the CA level, the BEOL process continues to form a conductive layer over the substrate, covering the CA level dielectric layer. The conductive layer, for example, may be processed to form metal lines of a first metal level M1 of the first ILD layer. The conductive layer, for example, is an aluminum layer. The conductive layer may be formed by physical vapor deposition (PVD). The conductive layer is processed to form one or more metal lines. The metal lines, in one embodiment, are formed by subtractive etch technique. For example, the conductive layer may be etched to form one or more conductors or metal lines using, for example, photoresist mask, patterning, and etch techniques. Other suitable types of conductive layer or forming techniques may also be useful, depending on the material of the conductive layer. M₁ and CA may be referred to as a lower ILD level 130l.

After forming metal lines of the first metal level, the BEOL process continues to form additional ILD layers. For example, the process continues to form intermediate ILD levels 130i. Intermediate ILD levels may include ILD level 2 to ILD level x-1. For example, in the case where x=5 (5 levels), the intermediate levels include ILD levels from 2 to 4, which includes metal levels M₂ to M₄ and via or contact levels V₁ to V₃. Typically, a device may have about 3-7 (e.g., x=3-7) metal levels. Providing devices with other number of metal levels may also be useful.

The number of ILD layers may depend on, for example, design requirements or the logic process involved. These ILD layers may be referred to as intermediate ILD layers 130i. The intermediate ILD layers may be formed of silicon oxide. Other suitable types of dielectric materials, such as low k, high k or a combination of dielectric materials may also be useful. The ILD layers may be formed by, for example, CVD, plasma enhanced CVD (PECVD), high density plasma CVD (HDP CVD) or a combination thereof. Other suitable techniques for forming the ILD layers may also be useful. Metal lines (not shown) are disposed in metal level dielectric while contacts (not shown) are disposed in via or contact level dielectric of the respective ILD levels of the intermediate ILD layers 130i. The metal lines and contacts of the intermediate ILD layers may be formed by the same materials and same techniques as described with respect to the metal lines and contacts of the lower ILD level as described above.

An upper ILD level 130u is provided over the top of the intermediate ILD layers. The upper ILD level includes metal level Mx and via level Vx-1. The intermediate ILD layer beneath the upper ILD layer includes Mx-1 and Vx-2. For example, in the case where the device includes 5 metal levels, the upper ILD level includes M5 and V4. Metal lines and contacts in the upper ILD layers may be formed by the same materials and same techniques as described with respect to the metal lines and contacts in the intermediate and lower ILD layers. For example, as described, the contacts in the via level may be formed by single damascene while the metal lines in the metal level may be formed by subtractive etch technique. Other suitable techniques, such as damascene technique, may also be employed to form the via contacts and metal lines of the ILD levels.

The upper ILD level may have different design rules, such as critical dimension (CD), than the intermediate ILD layers. For example, upper ILD layer may have a larger CD than the intermediate ILD layers. For example, the upper ILD layer may have a CD which is 2× or 6× the CD of the intermediate ILD layers. One or more metal lines 154 are disposed in the metal level dielectric 150 while one or more contacts 144 are disposed in the via level dielectric 140 of the upper ILD level. The contact 144 is disposed in the via level Vx-1 in between the top most metal level Mx and its adjacent underlying lower metal level Mx-1. Metal lines 154 of the upper ILD level may be about 2× to 6× larger and thicker than metal lines (not shown) in intermediate or lower ILD layers.

The conductive material of the metal lines and dielectric material of the dielectric layer in an ILD level have different thermal coefficients. During thermal processing, such as alloy heating and cooling processes which are performed after forming the top most metal level, the large and thick metal line in the upper ILD level expands and shrinks at a greater rate relative to the adjacent dielectric layers. We have observed that the expansion and shrinkage of the thick metal line in the upper ILD level may exert stress on the adjacent dielectric layers. Such stress may weaken the interface adhesion between different ILD layers. Moreover, when the stress at the interface of the different dielectric layers is greater than the hardness of the dielectric layer, this may cause initial stress cracks in dielectric layer which may permeate downwards into the intermediate ILD layers, following the weak points in these dielectric layers. This can negatively affect performance and reliability of the device.

In one embodiment, a crack stop layer 160 is disposed in the upper ILD level to counter the stress. The crack stop layer, in one embodiment, is disposed in the contact or via level dielectric of the upper ILD layer. The crack stop layer may be disposed anywhere within the via level dielectric as long as it can prevent crack propagation. In one embodiment, the crack stop layer is disposed in an upper portion or top of the via level dielectric in the upper ILD level. The crack stop layer, in one embodiment, is disposed in an upper portion of the via level dielectric of the upper ILD level as shown in FIG. 1a. In such case, the via level dielectric 140 includes a dielectric stack having an upper via dielectric layer 147 and a lower via dielectric layer 145 while the crack stop layer 160 is disposed between layers 145 and 147. As shown in FIG. 1a, the crack stop layer 160 is disposed below the large or thick metal line 154 of the upper ILD level and near to the top surface 140a of the via level dielectric 140. The via contact 144 is disposed in the via level dielectric 140 penetrating the upper via dielectric layer 147, the crack stop layer 160, and the lower via level dielectric layer 145.

In another embodiment, the crack stop layer 160 is disposed on top of the via level dielectric 140 of the upper ILD level as shown in FIG. 1b. In such case, the via level dielectric 140 includes a single dielectric layer and the crack stop layer 160 is disposed over the top surface 140a of the via level dielectric 140. As shown in FIG. 1b, the crack stop layer is disposed below the large or thick metal line 154 and in between the metal level dielectric 150 and via level dielectric 140 of the upper ILD level. The via contact 144, as shown, is disposed in the via level dielectric 140 and penetrates the crack stop layer 160 and the via level dielectric layer 140. The via contact 144, in one embodiment, includes a top surface which is substantially coplanar with top surface of the crack stop layer as shown in FIG. 1b.

The crack stop layer 160 is made of, for example, silicon nitride or any other suitable hard material which provides sufficient resistance to prevent crack formation and/or propagation. The crack stop layer includes a thickness of, for example, about 1000 Å. Other suitable thickness dimensions may also be useful, depending on the mechanical strength provided by this crack stop layer and the actual needs, as well as the consideration of higher capacitance.

As shown in FIGS. 1a-1b, a capping layer 170 covers the upper ILD level. A pad dielectric layer or level (not shown) having a pad interconnect (not shown) is disposed over the capping layer 170. The pad interconnect includes a pad via contact in the pad via level and a contact pad in the pad contact level. The pad via contact is electrically coupled to the interconnect 154 in the upper ILD level 130u. The pad interconnect, in one embodiment, is an aluminum pad interconnect. Other suitable conductive materials, such as but not limited to copper, may also be used to serve as the pad interconnect. In one embodiment, the pad via contact and the contact pad may be formed of the same material. For example, the pad via contact and contact pad may be formed of aluminum. The pad via contact and contact pad, for example, may be an integral unit. For example, the pad via contact and contact pad are formed by a dual damascene process. The dual damascene process may be via first or via last process.

As described, the crack stop layer is disposed in the upper ILD level to prevent crack formation and/or crack propagation in the dielectric layer as a result of the stress generated due to expansion and shrinkage of the large and thick metal line in the upper ILD level during thermal processes. As circuitry designs differ, the weak areas of the ILD layers differ also. Additional weak areas other than that found in the upper ILD level may exist. Actual wafer examination such as in-line SEM or in-line focused in beam (FIB) may detect cracks. Yield or reliability tests may also detect cracks in the circuits. A stress simulation test may predict the weak areas in a particular circuit. A crack stop layer 160 may be disposed in weak areas of ILD layers as indicated by the examination and/or stress simulation.

FIG. 1c shows a simplified cross-sectional view of a portion of the ILD layers 130 illustrated in FIGS. 1a-b. FIG. 1c illustrates the provision of a crack stop layer to prevent crack formation and/or crack propagation in an ILD layer. The ILD layer may be any ILD level of the ILD layers 130 where weak areas exist and high stress profile may have been observed using the stress simulation as described in the preceding paragraph. The ILD layer where weak areas exist may be the i^{th} ILD level of x ILD levels. Referring to FIG. 1c, a via or contact level of the i^{th} ILD level may be referred to as Vᵢ₋₁ and the metal level of the i^{th} ILD level may be referred to as Mᵢ. The via level Vᵢ₋₁, as shown, is disposed between the metal level Mᵢ and the next lower metal level Mᵢ₋₁.

One or more contacts 144ᵢ₋₁ are disposed in via level dielectric 140ᵢ₋₁ of the i^{th} ILD level. One or more metal lines 154ᵢ are disposed in metal level dielectric 150ᵢ of the i^{th} ILD level and one or more metal lines 154ᵢ₋₁ are disposed in the metal level dielectric 150ᵢ₋₁ below the i^{th} ILD level. Depending on the process, the via level dielectric 140ᵢ₋₁ and the metal level dielectric 150ᵢ₋₁ may be formed by the same dielectric layer. Alternatively, the via level dielectric 140ᵢ₋₁ and metal level dielectric 150ᵢ₋₁ may also be formed by separate dielectric layers. In one embodiment, a crack stop layer 160 may be disposed anywhere within the via level dielectric 140ᵢ₋₁ as long as it can prevent crack propagation. In one embodiment, the crack stop layer 160 is disposed in an upper portion or top of the via level dielectric 140ᵢ₋₁. The crack stop layer, in one embodiment, is disposed in an upper portion of the via level dielectric 140ᵢ₋₁ as shown in FIG. 1c. In such case, the via level dielectric 140ᵢ₋₁ includes a dielectric stack having an upper via dielectric layer 147 and a lower via dielectric layer 145 and the crack stop layer 160 is disposed between layers 145 and 147. The via contact 144ᵢ₋₁ is disposed in the via level dielectric 140ᵢ₋₁ penetrating the upper via dielectric layer 147, the crack stop layer 160, and the lower via dielectric layer 145.

In other embodiments, the crack stop layer 160 is disposed on top of the via level dielectric 140ᵢ₋₁. In such case, the via level dielectric 140ᵢ₋₁ includes a single dielectric layer and the crack stop layer 160 is disposed over the top surface 140a of the via level dielectric 140ᵢ₋₁. The crack stop layer, for example, is disposed directly beneath metal level dielectric 150ᵢ. The via contact, for example, is disposed in the via level dielectric 140ᵢ₋₁ and penetrates the crack stop layer and the via level dielectric. The via contact, in this embodiment, includes a top surface which is substantially coplanar with top surface of the crack stop layer similar to that shown in FIG. 1b.

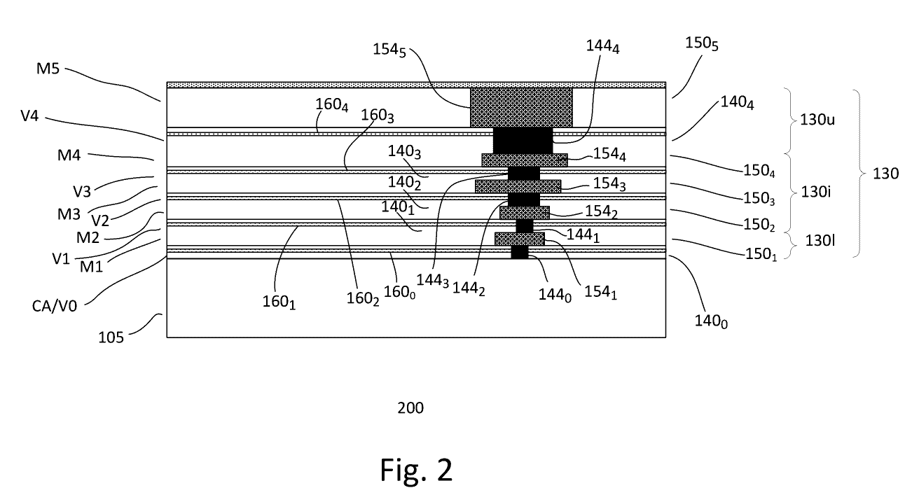

FIG. 2 shows another embodiment of a device 200. The device 200, is similar to the device 100 shown in FIGS. 1a-1b. Thus, in the interest of brevity, common elements or elements with the same reference numerals will not be described or described in detail.

As shown in FIG. 2, the device 200 includes a substrate 105 and ILD layers 130 disposed over the substrate. For illustration purpose, 5 ILD levels are provided. Other suitable number of ILD levels may also be useful. An ILD level includes a metal level and a via level. Metal lines are disposed in the metal level dielectric of the metal level while via contacts are disposed in the via level dielectric of the via level. As shown in FIG. 2, some reference numerals may include a subscript. The subscript indicates which via or metal level that the element is associated. For example, a reference numeral with a subscript 1 indicates that the element is associated with the via or metal level 1; a reference numeral with a subscript 2 indicates that the element is associated with the via or metal level 2. For the first via or contact level, it may be referred to as CA or V0 while the first metal level or first interconnect level may be referred to as M1.

As shown in FIG. 2, the upper ILD layer 130u includes M5 and V4 of which metal lines 154₅ are disposed in metal level dielectric 150₅ and contacts 144₄ are disposed in via level dielectric 140₄. The lower ILD layer 130l includes M1 and CA/V0 where metal lines 154₁ are disposed in metal level dielectric 150₁ and contacts 144₀ are disposed in via level dielectric 140₀. Intermediate ILD layers 130i include metal levels M2-M4 and contact levels V1-V3 respectively. Metal lines 154₂-154₄ are disposed in the respective metal level dielectric 150₂-150₄ and via contacts 144₁-144₃ are disposed in the respective via level dielectric 140₁-140₃ of the intermediate ILD layers.

As shown, each ILD layer typically gets thicker as the ILD level is disposed further away from the transistors. The ILD level may have 1×, 2×, to 6× thickness from the bottom to the top of the device. The thicker the ILD level, the larger the metal interconnects. The larger the metal is, the more prone a stress crack is to occur. In one embodiment, crack stop layer may be disposed in each ILD layer where crack is prone to occur. For example, crack stop layers 160₀-160₄ are disposed, for example, in each of the via level dielectric of the ILD layers 130 having 5 ILD levels. The crack stop layer may also be disposed in each ILD layer where capacitance requirement is not a critical factor in a device. The crack stop layer may be disposed anywhere within the via level dielectric of the ILD layers as long as it can prevent crack propagation. In one embodiment, the crack stop layers are disposed in upper portion or top of the via level dielectric. Referring to FIG. 2, the crack stop layers, for example, are disposed in an upper portion of the via level dielectric similar to that shown in FIG. 1a. In other embodiments, the crack stop layers may be disposed on top of the via level dielectric, similar to that shown in FIG. 1b. As shown in FIG. 2, crack stop layers are disposed in each via level dielectric layer. Depending on the circuitry design, crack stop layers may be disposed in one or more via level dielectrics where weak areas exist and high stress profile may have been observed using the stress simulation.

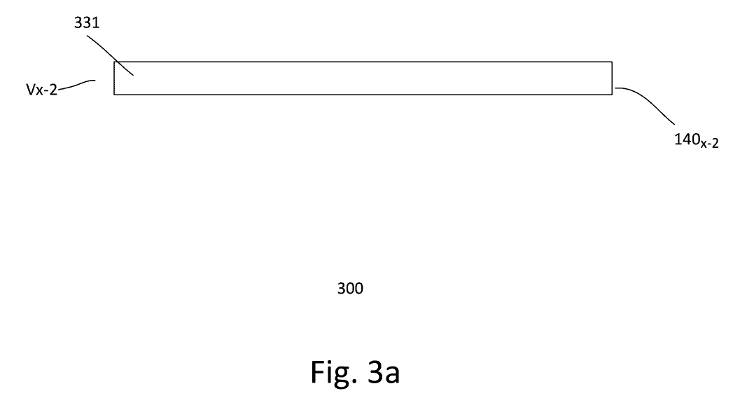

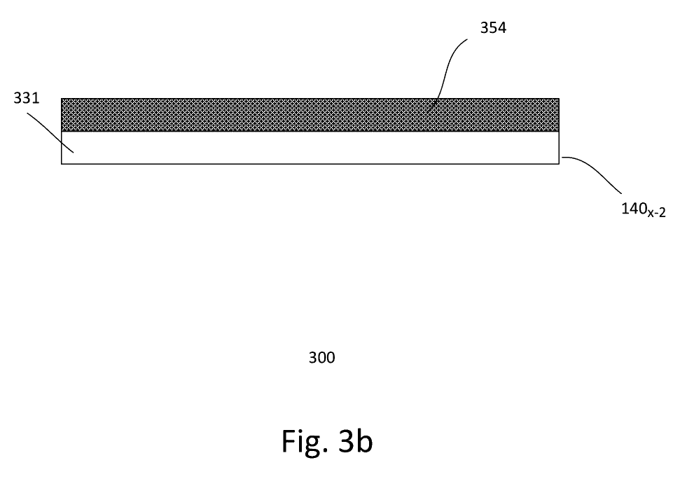

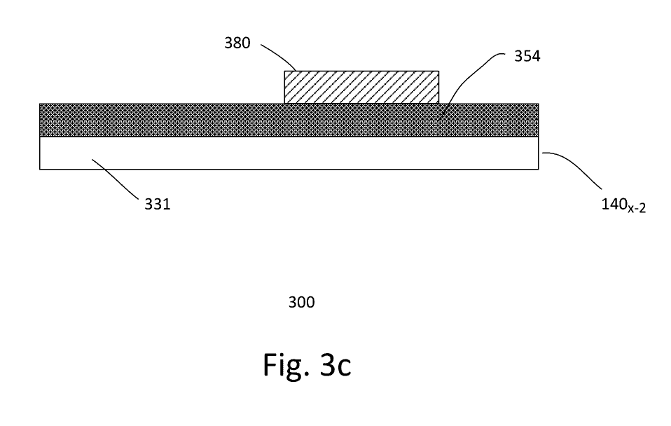

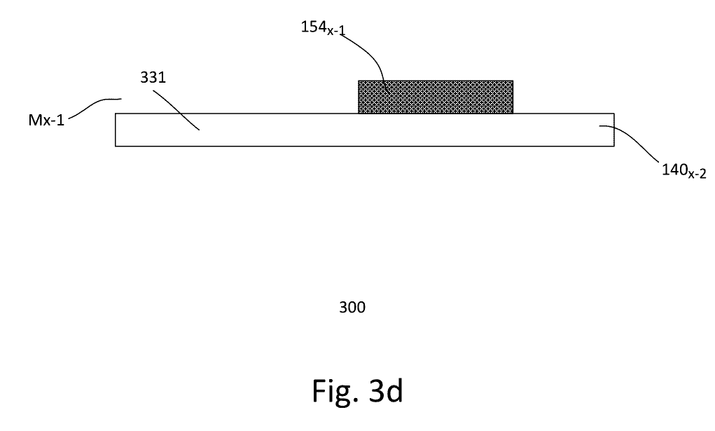

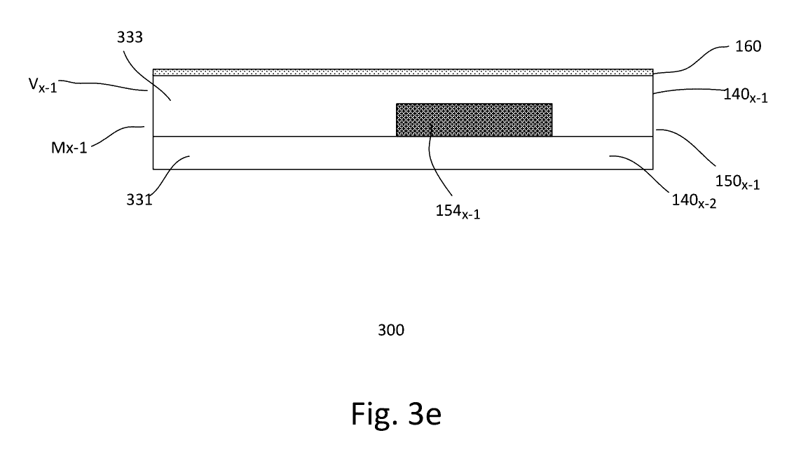

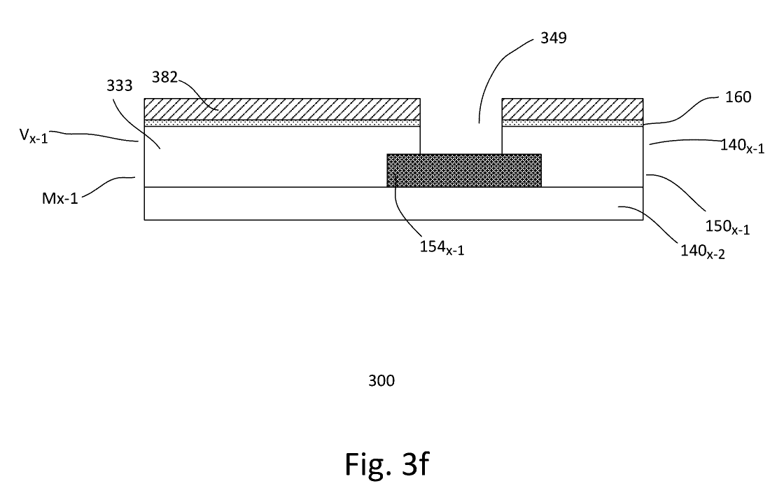

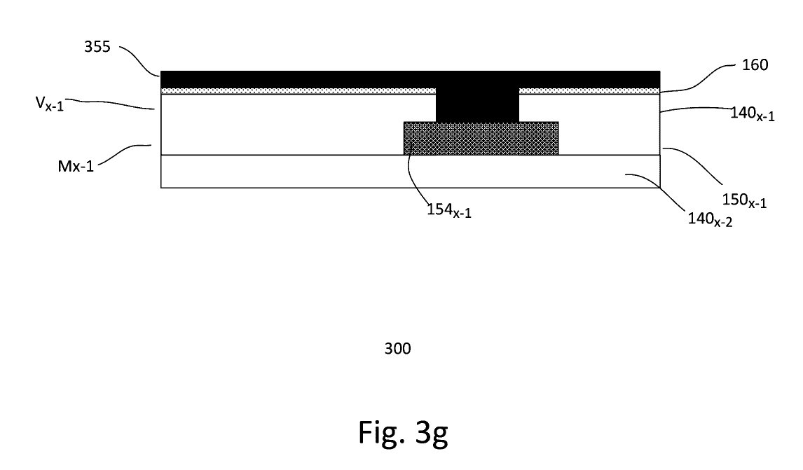

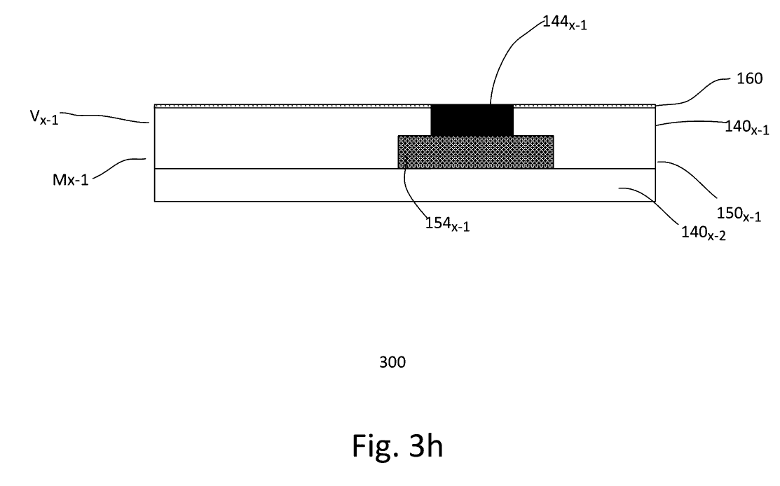

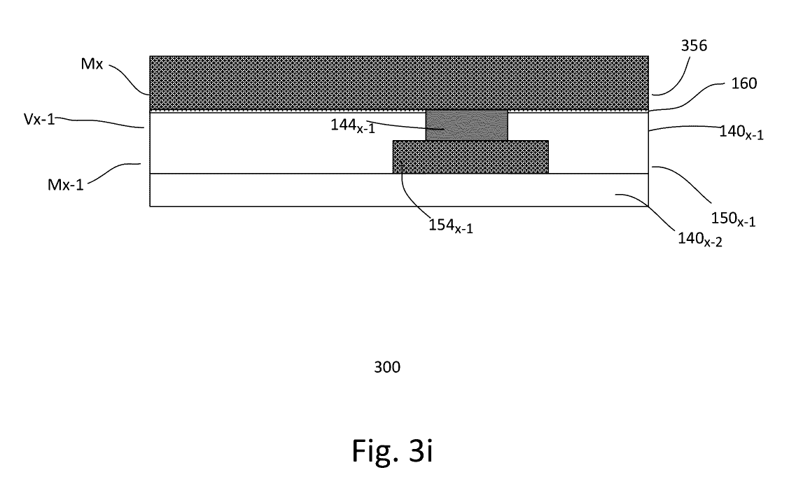

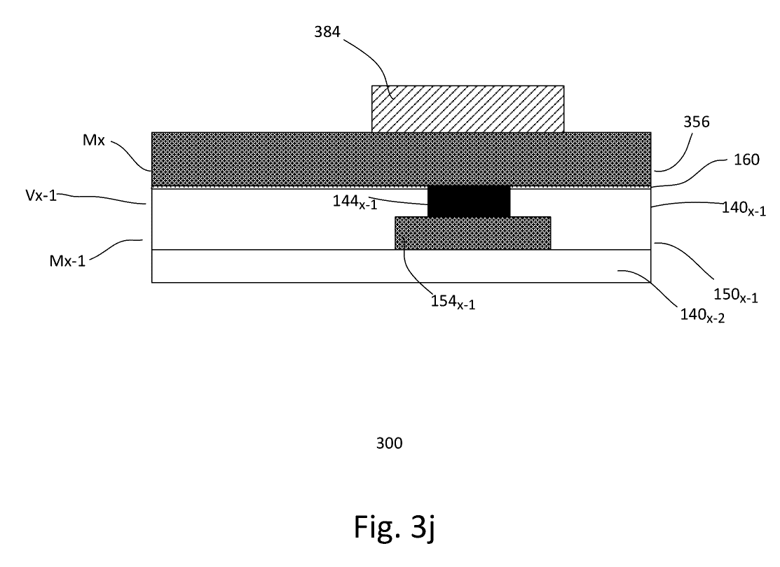

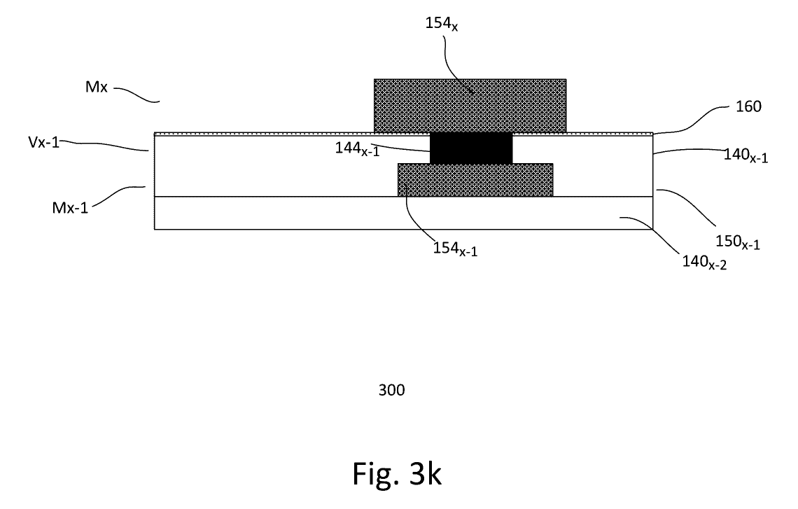

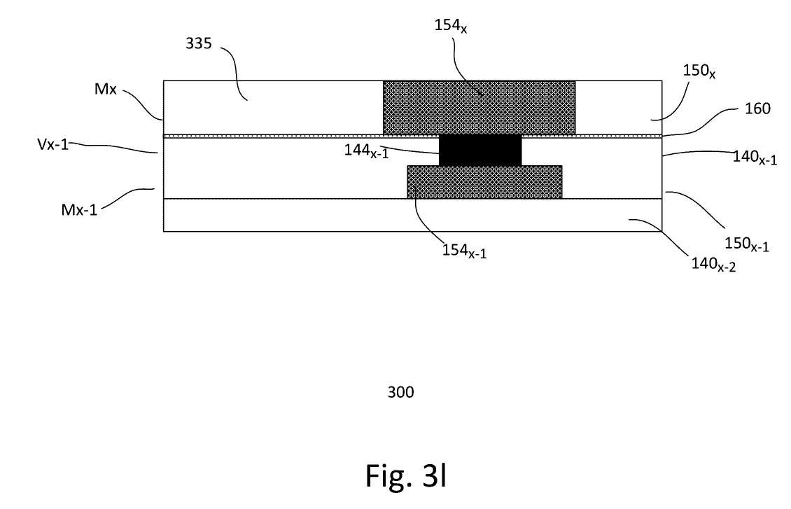

FIGS. 3a-3l show an embodiment of a process 300 for forming a device. The device formed is similar to that shown in FIG. 1b. Thus, common elements and features having the same reference numerals may not be described or described in detail.

For simplicity, the processing of a substrate to form transistors using FEOL and processing of lower ILD level and lower levels of the intermediate ILD level using BEOL are not shown. Referring to FIG. 3a, the process 300 is at the stage of providing a dielectric layer 331 over a substrate (not shown). The dielectric layer, for example, may correspond to via level dielectric 140ₓ₋₂ of via level Vₓ₋₂, where Vₓ₋₂ is the underlying via level of the metal level Mₓ₋₁. One or more via contacts (not shown) may be formed in this dielectric layer 331.

The dielectric layer 331 includes silicon oxide. Other suitable types of dielectric materials, such as BPSG (borophosphosilicone glass), PSG (phosphosilicate glass), organosilicate glass, fluorinated silicate glass, xerogel, or a polysilsequioxane, may also be useful. The dielectric layer may be formed by CVD, PECVD using tetraethylorthosilicate (TEOS) as a precursor, HDP CVD or a combination thereof. Other suitable techniques may also be useful.

Referring to FIG. 3b, the process continues by providing a conductive layer 354 over the dielectric layer 140ₓ₋₂. The conductive layer 354, in one embodiment, includes aluminum and is formed by PVD with Ti/TiN PVD barrier (not shown). Other suitable conductive layer and forming techniques may also be useful, depending on the material of the conductive layer. For example, in the case where the conductive layer includes copper (Cu), it is typically formed with Ta/TaN barrier by PVD followed by Cu using electrochemical plating (ECP) technique, while in the case where the conductive layer includes tungsten, it is formed by PVD with Ti/TiN barrier followed by tungsten using CVD technique. The thickness of the conductive layer, for example, may be about 0.8 μm. Other suitable thickness may also be useful, depending on which metal level it corresponds to and depending on technology node.

The process continues to pattern the conductive layer to form one or more metal lines. A soft mask layer is formed on the conductive layer 354. The soft mask layer, in one embodiment, is a photoresist layer. The soft mask is patterned to form openings while covering portions of the conductive layer. To form the openings in the soft mask layer, it may be selectively exposed with an exposure source using a reticle. The pattern of the reticle is transferred to the photoresist layer after exposure by a development process. An anti-reflective coating (ARC) may be provided beneath the resist layer to improve lithographic resolution. The patterned resist layer 380, as shown in FIG. 3c, serves as an etch mask. For example, an anisotropic etch, such as RIE, patterns the conductive layer using the etch mask. The patterned resist is used to define one or more metal lines by removing portions of the conductive layer not protected by the patterned resist. The portion of the conductive layer under the patterned resist remains and forms the metal line 154ₓ₋₁ as shown in FIG. 3d. The metal line 154ₓ₋₁, for example, may correspond to metal line of metal level Mₓ₋₁, where Mₓ₋₁ is the underlying metal level of the top most metal level Mx. The metal line, as shown, is formed by subtractive etch process. Other suitable techniques for forming the one or more metal lines may also be useful, depending on the material of the metal lines. For example, in the case where the metal lines include Cu, the metal lines may be formed by damascene technique (not shown). The patterned mask is removed using suitable techniques, such as ashing, after forming the metal line.

Referring to FIG. 3e, a dielectric layer 333 is formed over the dielectric layer 331 and covers the one or more metal lines 154ₓ₋₁. The dielectric layer 333, for example, includes silicon oxide and may be formed by CVD, PECVD using TEOS as a precursor, HDP CVD or a combination thereof. For example, a dielectric layer having an initial thickness of about 0.6 μm is formed over the dielectric layer 331 using HDP CVD with high gap fill capabilities. PECVD process using TEOS as precursor may be performed to form additional dielectric material having thickness of about 1 μm followed by a CMP process to reduce the thickness and to planarize the surface, resulting in dielectric layer 333 with substantially planar surface. Other suitable dielectric materials and techniques for forming the dielectric layer 333 may also be useful. The dielectric layer 333 includes a final thickness of, for example, about 9000 Å. Other suitable thickness may also be useful, as long as it is sufficiently thick to provide metal level dielectric 150ₓ₋₁ for isolating adjacent metal lines 154ₓ₋₁ in the same metal level and to provide for via level dielectric 140ₓ₋₁ for accommodating one or more via contacts which will be formed later over the metal lines.

In one embodiment, a crack stop layer 160 is formed over the dielectric layer 333 as shown in FIG. 3e. The crack stop layer 160 includes, for example, silicon nitride or any other suitable hard material which provides sufficient resistance to prevent crack formation and/or propagation. The crack stop layer, such as silicon nitride, is formed over the dielectric layer 333 by PECVD. The crack stop layer includes a thickness of, for example, about 1000 Å. Other suitable thickness dimensions and other suitable techniques may also be useful.

The process continues to form one or more via openings 349 through the crack stop layer 160 and the dielectric layer 333 as shown in FIG. 3f. To form the one or more via openings, mask and etch techniques can be employed. For example, a mask 382, such as a photoresist, can be used to form the via opening. The mask is selectively exposed and developed to create the desired via opening patterns. The mask, for example, includes a pattern which protects or covers the crack stop layer except where via openings are to be formed. Exposed portions of the crack stop layer and underlying dielectric material which are not covered by the mask pattern are removed by, for example, a dry etch or RIE. For example, via opening 349 formed through the crack stop layer and the underlying dielectric layer 333 and exposes portion of the metal line 154ₓ₋₁. The mask is removed using suitable techniques, such as ashing.

The process continues with the formation of via contact or contact plug. The opening 349, for example, may be lined with a barrier layer (not shown), such as TiN/Ti using sputtering. Other suitable types of barrier material may also be used, depending on the material of the via contact. A conductive layer 355 is formed over the crack stop layer and fills the opening 349 as shown in FIG. 3g. The conductive layer 355, in one embodiment, includes tungsten and is formed by CVD. Excess conductive material is removed by CMP, forming via contact 144ₓ₋₁ of via level Vₓ₋₁ which is coupled to the metal line 154ₓ₋₁ as shown in FIG. 3h. The CMP may also partially remove and reduce the thickness of the crack stop layer 160. The via contact 144ₓ₋₁, as shown, is formed by a single damascene process. Other suitable types of conductive material, barrier material and forming techniques may also be employed. The via contact, as shown, includes a top surface which is substantially coplanar with top surface of the crack stop layer.

Referring to FIG. 3i, the process continues by forming a conductive layer 356 over the crack stop layer 160 and covers the via contact 144ₓ₋₁. The conductive layer, in one embodiment, includes the same material and is formed by the same technique as that described with respect to conductive layer 354. Other suitable conductive material and forming techniques may also be useful. The thickness of the conductive layer, for example, may be about 36000 Å. Other suitable thickness may also be useful as long as it is sufficiently thick to serve as the top most metal line and depends on technology node.

The process continues to pattern the conductive layer 356 to form one or more metal lines. This can be achieved using mask and etch techniques, the same as that described in FIGS. 3c-3d. The patterned resist layer 384, as shown in FIG. 3j, serves as an etch mask. For example, an anisotropic etch, such as a RIE, patterns the conductive layer using the etch mask. The patterned resist is used to define the one or more metal lines by removing portions of the conductive layer not protected by the patterned resist. The portion of the conductive layer under the patterned resist remains and forms the metal line 154ₓ as shown in FIG. 3k. The metal line 154ₓ, for example, may correspond to metal line of metal level Mₓ, which is the top most metal level of the device. The metal line, as shown, is formed by subtractive etch process. Other suitable techniques for forming the one or more metal lines of the top most metal level may also be useful, depending on the material of the metal lines. The patterned mask is removed using suitable techniques, such as ashing.

Referring to FIG. 3l, a dielectric layer 335 is formed over the crack stop layer 160 and covers the one or more metal lines 154ₓ. The dielectric layer 335, for example, includes the same material and is formed by the same techniques as that described for dielectric layer 333. A CMP may be performed to provide a planar top surface for the dielectric layer 335. Other suitable dielectric materials and techniques for forming the dielectric layer 335 may also be useful. The dielectric layer 335 includes a thickness of, for example, about 35000 Å. Other suitable thickness may also be useful, as long as it is sufficiently thick to provide metal level dielectric 150ₓ for isolating adjacent metal lines 154x in the same metal level. The metal line 154ₓ, for example, includes a top surface which is substantially coplanar with the top surface of the dielectric layer 335.

The process continues to complete formation of the IC. The process, for example, may continue to form passivation layer and pad interconnects or bonding pads. Further processing can include final passivation, dicing, assembly and packaging. Other processes are also useful.

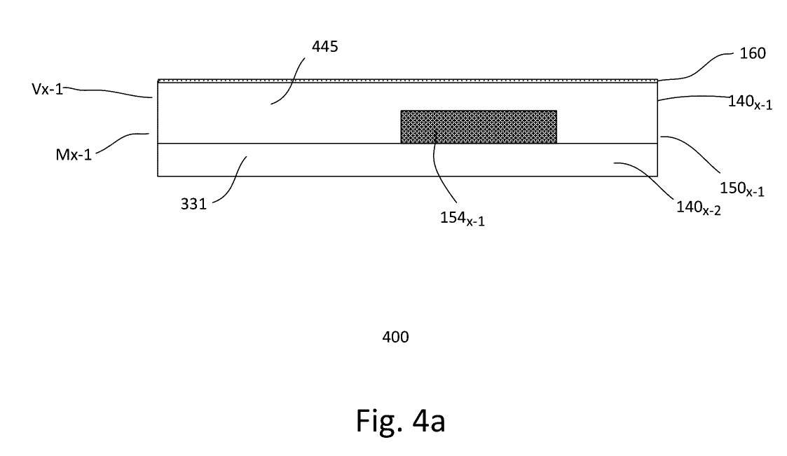

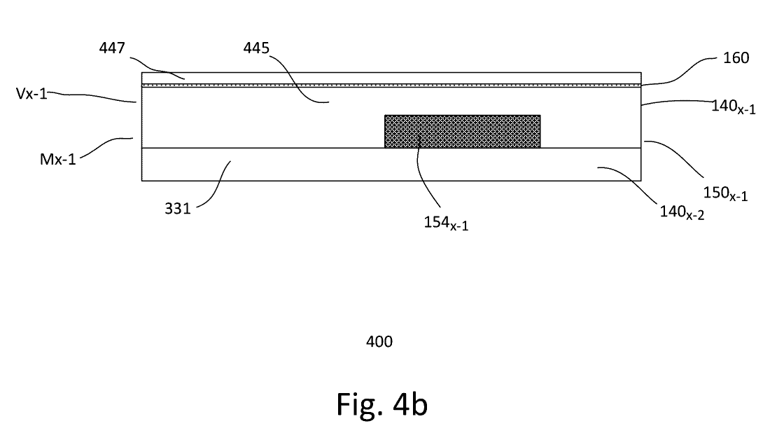

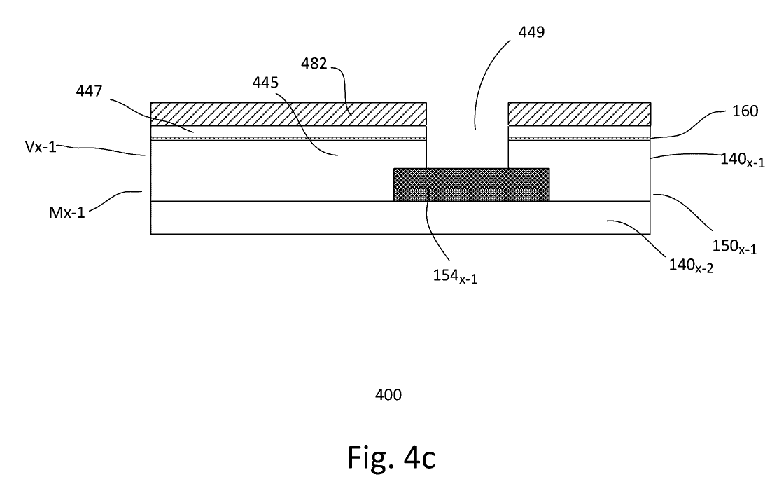

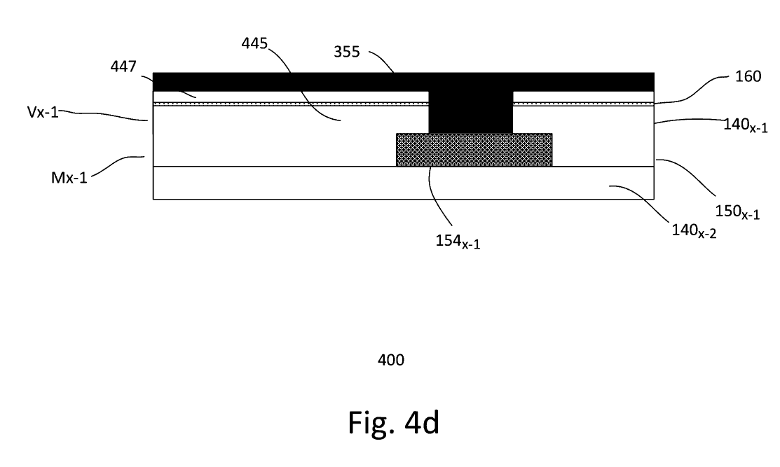

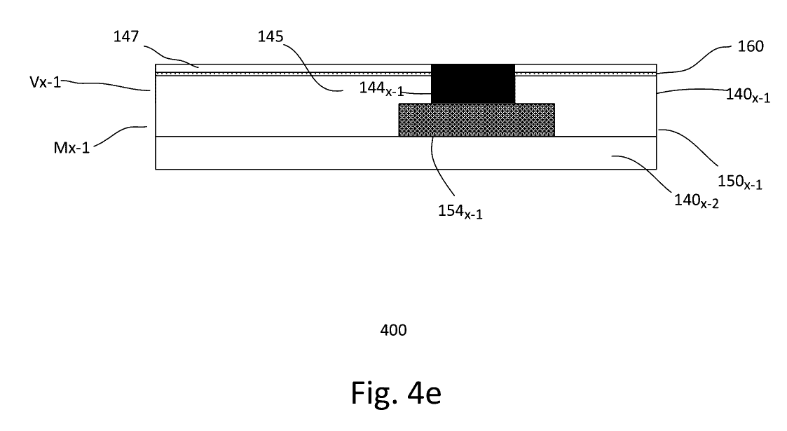

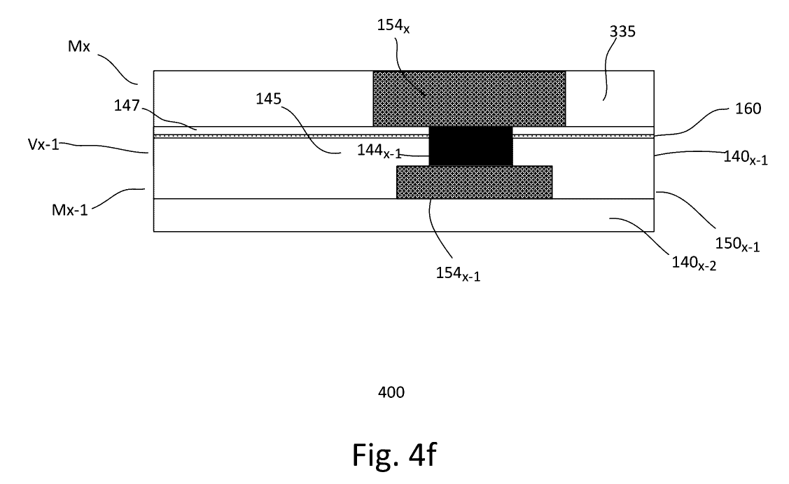

FIGS. 4a-4f show another embodiment of a process 400 for forming a device. The process 400 is similar to the process 300 as shown in FIGS. 3a-3l and the device formed is similar to that shown in FIG. 1a. Thus, common elements and features having the same reference numerals may not be described or described in detail.

Referring to FIG. 4a, the process 400 is at the stage similar to that described in FIG. 3e. For example, a dielectric layer 445 having an initial thickness of, for example, about 10000 Å is formed over the dielectric layer 331 and covers the one or more metal lines 154ₓ₋₁. The dielectric layer 445 may be formed using HDP CVD process to facilitate gap fill and excess dielectric material may be removed by CMP process to reduce the thickness to about, for example, 6000 Å. A crack stop layer 160 having a thickness of about, for example, 1000 Å, is formed over the dielectric layer 445 by PECVD. Other suitable thickness dimensions, materials and techniques may also be employed.

In one embodiment, the process continues to form a dielectric layer 447 over the crack stop layer as shown in FIG. 4b. The dielectric layer, for example, includes silicon oxide having a thickness of about 3000 Å and may be formed by PECVD using TEOS as precursor. Other suitable thickness may also be useful as long as the total thickness of the dielectric layer 447 and portion of the dielectric layer 445 above the metal line 154ₓ₋₁ are sufficiently thick to provide via level dielectric 140ₓ₋₁ for accommodating one or more via contacts which will be formed later over the metal lines. Forming the dielectric layer 447 using other suitable techniques may also be useful.

The process continues to form one or more via openings 449 through the dielectric layer 447, crack stop layer 160 and the dielectric layer 445 as shown in FIG. 4c. To form the one or more via openings, mask and etch techniques can be employed. For example, a mask 482, such as a photoresist, can be used to form the via opening. The mask is selectively exposed and developed to create the desired via opening patterns. The mask, for example, includes a pattern which protects or covers the dielectric layer 447 except where via openings are to be formed. Exposed portions of the dielectric layer 447 and underlying crack stop and dielectric materials which are not covered by the mask pattern are removed by, for example, a dry etch or RIE. For example, via opening 449 is formed through the dielectric layer 447, crack stop layer 160 and the underlying dielectric layer 445, exposing portion of the metal line 154ₓ₋₁. The mask is removed using suitable techniques, such as ashing.

The process continues with the formation of via contact or contact plug. A conductive layer 355 is formed over the crack stop layer and fills the via opening 449 as shown in FIG. 4d. Excess conductive material is removed by CMP, forming via contact 144ₓ₋₁ which is coupled to the metal line 154ₓ₋₁ as shown in FIG. 4e. The CMP may also partially remove and reduce the thickness of the dielectric layer 447 to form dielectric 147. Materials and techniques for forming the via contact are the same as that described in FIGS. 3g-3h. The via contact 144ₓ₋₁, as shown, is formed by a single damascene process. Other suitable types of conductive material, barrier material and forming techniques may also be employed. The via contact is formed in the via level dielectric 140ₓ₋₁ which includes a dielectric stack having an upper via dielectric 147 and a lower via dielectric 145 while the crack stop layer 160 is disposed between layers 145 and 147.

Referring to FIG. 4f, the process continues by forming a conductive layer over the dielectric layer 147 and covers the via contact 144ₓ₋₁. The process continues to pattern the conductive layer to form one or more metal lines 154ₓ which may correspond to metal line of metal level Mₓ, which is the top most metal level of the device. A dielectric layer is formed over the dielectric layer 147 and covers the one or more metal lines 154ₓ. A CMP may be performed to provide a planar top surface for the dielectric layer 335. The metal line 154ₓ, for example, includes a top surface which is substantially coplanar with the top surface of the dielectric layer 335. Materials and techniques for forming the metal line 154ₓ and dielectric layer 335 are the same as that described in FIGS. 3i-3l. Other suitable materials and techniques may also be useful.

The process continues to complete formation of the IC. The process, for example, may continue to form passivation layer and pad interconnects or bonding pads. Further processing can include final passivation, dicing, assembly and packaging. Other processes are also useful.

For illustration purpose, FIGS. 3a-3l and FIGS. 4a-4f show that a crack stop layer is formed in a via level dielectric which is below the large and thick metal line of the upper ILD level to prevent crack formation and/or crack propagation. It is understood that the methods described in FIGS. 3a-3l and FIGS. 4a-4f may be modified to form one or more crack stop layers in via dielectric of any ILD levels where weak areas other than that found in the upper ILD level may exist. The crack stop layer improves the resistance of the ILD layer against stress generated due to coefficient of thermal expansion (CTE) mismatch between metal and dielectric during thermal processing. This prevents crack formation and/or crack propagation in the ILD layer and thus improves the reliability of the device. Moreover, as described, the contacts, such as tungsten contacts, in the via level may be formed by single damascene while the metal lines, such as aluminum metal lines, in the metal level may be formed by subtractive etch technique. It is understood that various suitable conductive materials may be used for the contacts in the via level and the metal lines in the metal level and the forming techniques may vary, depending on the materials of the contacts and metal lines.

In this disclosure, certain words are used interchangeably as known to those skilled in the art. For example, the terms of “level” and “layer” are used interchangeably in this description. The word “level” generally refers to spatial relationship of the embodiment while the word “layer” generally refers to physical material of the embodiment. Additionally, certain singular words apply to plural words and certain plural words apply to singular words.

The disclosure may be embodied in other specific forms without departing from the spirit or essential characteristics thereof. The foregoing embodiments, therefore, are to be considered in all respects illustrative rather than limiting the disclosure described herein. Scope of the disclosure is thus indicated by the appended claims, rather than by the foregoing description, and all changes that come within the meaning and range of equivalency of the claims are intended to be embraced therein.

What is claimed is:

1. A method for forming a device comprising:
providing a substrate prepared with a plurality of interlevel dielectric (ILD) layers having interconnect levels, wherein each of the ILD layers comprises
a metal level dielectric which includes one or more metal lines,
a via level dielectric which includes one or more via contacts;
performing at least one of actual wafer examination and stress simulation test to identify weak areas in the ILD layers; and
forming a crack stop layer on top of the via level dielectric of one or more ILD layers with at least a weak area, wherein the crack stop layer prevents crack formation in the ILD layer or crack propagation to underlying ILD layer.

2. The method of claim 1 wherein the plurality of ILD layers of the device comprise:
a lower ILD layer over the substrate and having an interconnect level which includes a metal level M₁ and a via level V₀ over the substrate, wherein M₁ is the lowest metal level and V₀ is the lowest via level;
a plurality of intermediate ILD layers over the lower ILD layer and having interconnect levels which include metal levels M₂ to Mₓ₋₁ and via levels V₁ to Vₓ₋₂; and
an upper ILD layer over the intermediate ILD layers and having an interconnect level which includes metal level Mₓ and via level Vₓ₋₁, wherein Mₓ is the top-most metal level and Vₓ₋₁ is the top-most via level, wherein
the upper ILD layer comprises at least a metal line formed in metal level dielectric and at least a via contact formed in via level dielectric, wherein
the crack stop layer is formed on top of the via level dielectric of the upper ILD layer.

3. The method of claim 2 wherein the crack stop layer comprises of a hard material which provides sufficient resistance to prevent at least one of crack formation and propagation including silicon nitride.

4. The method of claim 2 wherein the via contacts and the metal lines comprise of aluminum, tungsten, copper or alloy thereof.

5. The method of claim 2 wherein the upper ILD layer is formed by forming a first dielectric layer which corresponds to the via level dielectric of the upper ILD layer over the intermediate ILD layers.

6. The method of claim 5 wherein the via contact in the via level dielectric of the upper ILD layer is formed by:
forming at least a via opening through the crack stop layer and the first dielectric layer of the via level dielectric of the upper ILD layer;
forming a first conductive layer over the crack stop layer and fills the via opening; and
removing excess conductive material of the first conductive layer to form the via contact having a top surface which is substantially coplanar with top surface of the crack stop layer.

7. The method of claim 6 wherein the metal line in the metal level dielectric of the upper ILD layer is formed by:
forming a second conductive layer over the crack stop layer and covers the via contact; and
patterning the second conductive layer to form the metal line by subtractive etch process.

8-14. (canceled)

15. A device comprising:
a substrate prepared with a plurality of interlevel dielectric (ILD) layers having interconnect levels, wherein each of the ILD layers comprises
a metal level dielectric which includes one or more metal lines,
a via level dielectric which includes one or more via contacts; and
a crack stop layer disposed within at least one of the ILD layers with at least a weak area as indicated by at least one of actual wafer examination and stress simulation test, wherein the crack stop layer prevents crack formation in the ILD layer or crack propagation to underlying ILD layer.

16. The device of claim 15 wherein the crack stop layer comprises of a hard material which provides sufficient resistance to prevent at least one of crack formation and propagation including silicon nitride.

17. The device of claim 15 wherein the crack stop layer is disposed on top of the via level dielectric of the ILD layer.

18. The device of claim 15 wherein the crack stop layer is disposed in an upper portion of the via level dielectric of the ILD layer.

19. The device of claim 18 wherein the via level dielectric of the ILD layer comprises a lower via dielectric and an upper via dielectric, wherein the crack stop layer is disposed in-between the lower via dielectric and the upper via dielectric.

20. The device of claim 15 wherein the one or more via contacts and the metal lines comprise of aluminum, tungsten, copper or alloy thereof.

21. A method for forming a device comprising:
providing a substrate prepared with a plurality of interlevel dielectric (ILD) layers having interconnect levels, wherein each of the ILD layers comprises
a metal level dielectric which includes one or more metal lines,
a via level dielectric which includes one or more via contacts;
performing at least one of actual wafer examination and stress simulation test to identify weak areas in the ILD layers; and
forming a crack stop layer within the via level dielectric of one or more ILD layers with at least a weak area, wherein the crack stop layer prevents crack formation in the ILD layer or crack propagation to underlying ILD layer.

22. The method of claim 21 wherein the plurality of ILD layers of the device comprise:
a lower ILD layer over the substrate and having an interconnect level which includes a metal level M₁ and a via level V₀ over the substrate, wherein M₁ is the lowest metal level and V₀ is the lowest via level;
a plurality of intermediate ILD layers over the lower ILD layer and having interconnect levels which include metal levels M₂ to Mₓ₋₁ and via levels V₁ to Vₓ₋₂; and
an upper ILD layer over the intermediate ILD layers and having an interconnect level which includes metal level Mₓ and via level Vₓ₋₁, wherein Mₓ is the top-most metal level and Vₓ₋₁ is the top-most via level, wherein
the upper ILD layer comprises at least a metal line formed in metal level dielectric and at least a via contact formed in via level, wherein
the crack stop layer is formed in an upper portion of the via level dielectric of the upper ILD layer.

23. The method of claim 22 wherein the crack stop layer comprises of a hard material which provides sufficient resistance to at least one of prevent crack formation and propagation including silicon nitride.

24. The method of claim 22 wherein the one or more via contacts and the metal lines comprise of aluminum, tungsten, copper or alloy thereof.

25. The method of claim 22 wherein the upper ILD layer is formed by:
forming a first dielectric layer over the intermediate ILD layer, wherein the first dielectric layer corresponds to a lower via dielectric of the via level dielectric of the upper ILD layer;
forming the crack stop layer over the lower via dielectric; and
forming a second dielectric layer over the crack stop layer, wherein the second dielectric layer corresponds to an upper via dielectric of the via level dielectric of the upper ILD layer.

26. The method of claim 25 wherein the via contact in the via level dielectric of the upper ILD layer is formed by:
forming at least a via opening through the crack stop layer and the upper and lower via dielectric of the via level dielectric;
forming a first conductive layer over the upper via dielectric and fills the via opening; and
removing excess conductive material of the first conductive layer to form the via contact having a top surface which is substantially coplanar with top surface of the upper via dielectric.

27. The method of claim 26 wherein the metal line in the metal level dielectric of the upper ILD layer is formed by:
forming a second conductive layer over the upper via dielectric of the upper ILD layer and covers the via contact; and
patterning the second conductive layer to form the metal line by subtractive etch process.
